(19) United States
(12) Patent Application Publication
(10) Pub. No.: US 2026/0251499 A1
(43) Pub. Date: Aug. 27, 2026

(54) PHOTODETECTOR AND PHOTODETECTION DEVICE

(71) Applicant: SONY SEMICONDUCTOR SOLUTIONS CORPORATION, Kanagawa (JP)

(72) Inventor: Hidenori MAEDA, Nagasaki (JP)

(73) Assignee: SONY SEMICONDUCTOR SOLUTIONS CORPORATION, Kanagawa (JP)

(21) Appl. No.: 18/870,812

(22) PCT Filed: Apr. 17, 2023
(86) PCT No.: PCT/JP2023/015347

§ 371 Date: Dec. 2, 2024

(30) Foreign Application Priority Data
Jun. 9, 2022 (JP) 2022-093915

(51) Int. Cl. G01J 1/44

(52) U.S. Cl. CPC G01J 1/44; G01J 2001/4466

(57) ABSTRACT

Provided are a photodetector and a photodetection device including a pixel array with sensitivity variation further reduced. A photodetector including a semiconductor substrate in which a photoelectric conversion section is provided, an inter-pixel light-shielding section that is provided over the semiconductor substrate and defines a light incident region of a pixel corresponding to the photoelectric conversion section, and an on-chip lens that is provided on the light incident region of the semiconductor substrate, in which at least edge sections of the on-chip lens in a diagonal direction of the pixel fall onto the light incident region.

### TECHNICAL FIELD

The present disclosure relates to a photodetector and a photodetection device.

### BACKGROUND ART

In recent years, a photodetector using an avalanche photodiode (APD) has attracted attention as a more sensitive photodetector. The APD can detect even weak light at high speed and high sensitivity by avalanche multiplication of electrons generated by the incident light.

On the other hand, since the APD has high sensitivity, the APD is more susceptible to noise and sensitivity variation than a commonly used photodiode. Therefore, a technique for reducing noise and sensitivity variation of the APD has been studied.

Various studies have been made on noise reduction of the APD. For example, Patent Document 1 below discloses a technique of reducing dark current of an avalanche photodiode by providing a hole storage region on a side wall of an isolation region provided between adjacent pixels.

### CITATION LIST

### Patent Document

Patent Document 1: Japanese Patent Application Laid-Open No. 2018-201005

### SUMMARY OF THE INVENTION

### Problems to be Solved by the Invention

On the other hand, the reduction of sensitivity variation in pixel arrays of the APDs has not been sufficiently studied.

Therefore, the present disclosure proposes a novel and improved photodetector and photodetection device capable of further reducing sensitivity variation in a pixel array.

### Solutions to Problems

According to the present disclosure, provided is a photodetector including a semiconductor substrate in which a photoelectric conversion section is provided, an inter-pixel light-shielding section that is provided over the semiconductor substrate and defines a light incident region of a pixel corresponding to the photoelectric conversion section, and an on-chip lens that is provided on the light incident region of the semiconductor substrate, in which at least edge sections of the on-chip lens in a diagonal direction of the pixel fall onto the light incident region.

In addition, according to the present disclosure, provided is a photodetection device including a photodetector, and a processing circuitry that performs signal processing on an output from the photodetector, in which the photodetector includes a semiconductor substrate in which a photoelectric conversion section is provided, an inter-pixel light-shielding section that is provided over the semiconductor substrate and defines a light incident region of a pixel corresponding to the photoelectric conversion section, and an on-chip lens that is provided on the light incident region of the semiconductor substrate, and at least edge sections of the on-chip lens in a diagonal direction of the pixel fall onto the light incident region.

### BRIEF DESCRIPTION OF DRAWINGS

FIG. 1 is a longitudinal cross-sectional view illustrating a cross-sectional configuration of a pixel array included in a photodetector according to a first embodiment.

FIG. 2 is a longitudinal cross-sectional view illustrating another cross-sectional configuration of a pixel array included in the photodetector according to the first embodiment.

FIG. 3 is a plan view illustrating a correspondence relationship between the cross-sectional configurations illustrated in FIGS. 1 and 2, and cutting lines on a plane of the pixel array.

FIG. 4 is a plan view illustrating a correspondence relationship between the cross-sectional configuration illustrated in FIG. 1 and cutting lines on a plane of a pixel array in a first modification.

FIG. 5 is a schematic diagram illustrating shapes of on-chip lenses in each of a center section and a peripheral section of a pixel array.

FIG. 6 is a schematic longitudinal cross-sectional view illustrating a first aspect of a positional relationship between an on-chip lens and an irregular section in a second embodiment.

FIG. 7 is a schematic longitudinal cross-sectional view illustrating a second aspect of a positional relationship between the on-chip lens and the irregular section in the second embodiment.

FIG. 8 is a schematic diagram illustrating shapes of on-chip lenses in each of a center section and a peripheral section of a pixel array.

FIG. 9 is a schematic diagram illustrating a configuration of a photodetection device that includes the photodetector according to the first or second embodiment.

FIG. 10 is a schematic diagram illustrating a configuration of a distance measuring device that includes the photodetection device illustrated in FIG. 9.

FIG. 11 is a block diagram illustrating an example of a schematic configuration of a vehicle control system.

FIG. 12 is an explanatory view illustrating an example of an installation position of an outside-vehicle information detecting section and an imaging section.

### MODE FOR CARRYING OUT THE INVENTION

Hereinafter, preferred embodiments of the present disclosure will be described in detail with reference to the accompanying drawings. Note that, in the present specification and drawings, components having substantially the same functional configuration are denoted by the same reference numerals to avoid the description from being redundant.

Note that explanation will be made in the following order.
1. First Embodiment
   1.1. Configuration of Pixels
   1.2. First Modification
   1.3. Second Modification
2. Second Embodiment
3. Application Example

### 1. First Embodiment

### 1.1. Configuration of Pixels

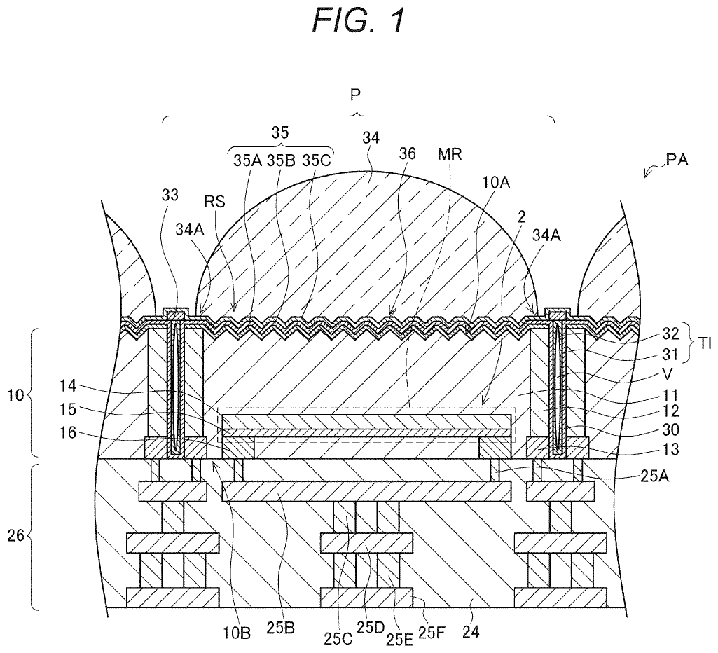

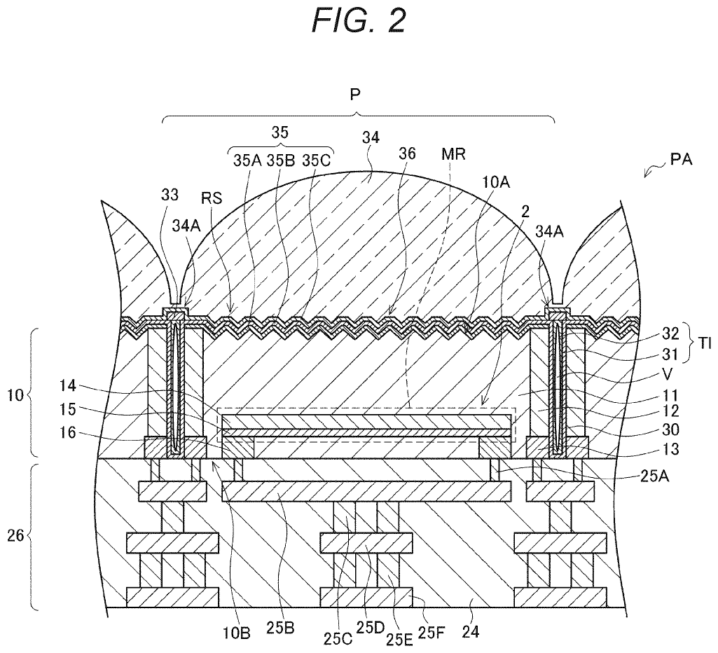

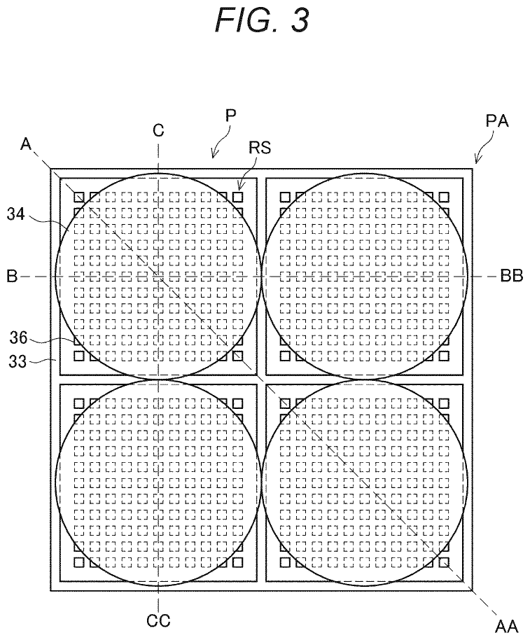

First, a configuration of pixels in a photodetector according to a first embodiment of the present disclosure will be described with reference to FIGS. 1 to 3. FIG. 1 is a longitudinal cross-sectional view illustrating a cross-sectional configuration of a pixel array PA included in the photodetector according to the present embodiment. FIG. 2 is a longitudinal cross-sectional view illustrating another cross-sectional configuration of the pixel array PA included in the photodetector according to the present embodiment. FIG. 3 is a plan view illustrating a correspondence relationship between the cross-sectional configurations illustrated in FIGS. 1 and 2, and cutting lines on a plane of the pixel array PA.

As illustrated in FIGS. 1 and 2, each of pixels P planarly arranged in the pixel array PA has a structure in which a wiring layer 26, a semiconductor substrate 10, and an on-chip lens 34 are stacked. The pixel P illustrated in FIGS. 1 and 2 has substantially the same configuration except for the difference that falling positions of the edge sections 34A of the on-chip lens 34 are different from each other.

Note that, in each of the pixels P, a surface of the semiconductor substrate 10 on which the on-chip lens 34 is provided is a light incident surface 10A. The light incident surface 10A is a surface obtained by polishing a back surface of the semiconductor substrate 10. On the other hand, the wiring layer 26 is bonded to a surface 10B of the semiconductor substrate 10 on the opposite side to the light incident surface 10A. That is, the photodetector according to the present embodiment is a so-called back-illuminated photosensor that receives light incident from the back surface of the semiconductor substrate 10.

The wiring layer 26 includes a plurality of wirings including a first wiring 25B, a second wiring 25D, and a third wiring 25F, which are embedded in an insulating film 24. The first wiring 25B, the second wiring 25D, and the third wiring 25F are connected to each other by, for example, a first connection layer 25C and a second connection layer 25E extending in a thickness direction of the wiring layer 26. The first wiring 25B is electrically connected to an anode or a cathode of a photoelectric conversion section 2 as described later via a contact layer 25A that extends in the thickness direction of the wiring layer 26. The third wiring 25F functions as a terminal for external connection by being exposed at the surface side of the wiring layer 26.

The contact layer 25A, the first wiring 25B, the second wiring 25D, the third wiring 25F, the first connection layer 25C, and the second connection layer 25E may include, for example, a metal such as copper (Cu), silver (Ag), gold (Au), aluminum (Al), tungsten (W), titanium (Ti), or tantalum (Ta), or a metal compound thereof. The insulating film 24 may include, for example, an inorganic insulating material such as silicon oxide (SiOₓ), silicon nitride (SiNₓ), or silicon oxynitride (SiON).

In the longitudinal cross-sectional views illustrated in FIGS. 1 and 2, the example in which three wiring layers of the first wiring 25B, the second wiring 25D, and the third wiring 25F are embedded in the insulating film 24 is illustrated, but the number of wiring layers embedded in the insulating film 24 is not particularly limited. In addition, in the longitudinal cross-sectional views illustrated in FIGS. 1 and 2, the example in which the insulating film 24 is configured as one layer is illustrated, but the insulating film 24 may be configured as a laminate of insulating films provided individually corresponding to the first wiring 25B, the second wiring 25D, the third wiring 25F, the contact layer 25A, the first connection layer 25C, and the second connection layer 25E.

The semiconductor substrate 10 includes, for example, a semiconductor material such as silicon (Si). In the semiconductor substrate 10, the photoelectric conversion section 2 is provided for each pixel P, and the adjacent pixels P are separated from each other by a pixel separation groove 30.

The pixel separation groove 30 is recessed in a thickness direction of the semiconductor substrate 10 to surround the pixel P. A pixel separation film TI is embedded in the pixel separation groove 30. The pixel separation film TI may be configured to, for example, cover the outside of a metal film 32 having a light shielding property such as tungsten (W) or aluminum (Al) with an insulating film 31 such as silicon oxide (SiOₓ), tantalum oxide (Ta₂O₅), hafnium oxide (HfO₂), or aluminum oxide (Al₂O₃). In addition, a void V may be provided inside the metal film 32. The pixel separation film TI can electrically and optically separate the adjacent pixels P from each other.

The photoelectric conversion section 2 is provided in the semiconductor substrate 10 and has a multiplication region MR for avalanche multiplication of electrons with a high electric field. The photoelectric conversion section 2 may be an avalanche photodiode (APD) or may be a single photon avalanche photodiode (SPAD).

Specifically, a well layer 11 is provided in the semiconductor substrate 10 separated for each of the pixels P by the pixel separation film TI. The well layer 11 is, for example, an n-type or p-type semiconductor region having a low concentration of 1×10¹⁴ atoms/cm³ or less. The well layer 11 is likely to be depleted by adopting a configuration of a low-concentration n-type or p-type semiconductor region, so that the photon detection efficiency (PDE) of the photoelectric conversion section 2 can be further enhanced.

In the well layer 11, a p-type semiconductor region 14 and an n-type semiconductor region 15 are provided in order from the light incident surface 10A side to form a pn junction. The p-type semiconductor region 14 is a high-concentration p-type semiconductor region (p+), and the n-type semiconductor region 15 is a high-concentration n-type semiconductor region (n+). The multiplication region MR is formed by applying a reverse voltage to the p-type semiconductor region 14 and the n-type semiconductor region 15.

A cathode 16 is provided between the n-type semiconductor region 15 and the contact layer 25A. Specifically, the cathode 16 is an n-type semiconductor region (n++) having a higher concentration than the n-type semiconductor region 15, and is provided to electrically connect the n-type semiconductor region 15 and the contact layer 25A. A predetermined bias voltage is applied from the contact layer 25A to the n-type semiconductor region 15 through the cathode 16.

A pinning layer 12 that accumulates holes (holes) is provided between the well layer 11 and the pixel separation film TI. The pinning layer 12 is a p-type semiconductor region and is provided to surround the side surface of the well layer 11 along the pixel separation film TI. For example, the pinning layer 12 may have a structure in which a p-type semiconductor region (p+) having a relatively high concentration and a p-type semiconductor region (p) having a relatively low concentration are sequentially stacked from the pixel separation film TI side. Fermi level pinning at an interface between the pixel separation film TI and the well layer 11 achieved by the pinning layer 12 enables occurrence of dark current at the interface to be reduced.

Furthermore, a bias voltage may be applied to the pinning layer 12 through an anode 13. According to this, since the pinning layer 12 can enhance the hole concentration, the Fermi level at the interface between the pixel separation film TI and the well layer 11 can be more firmly pinned.

The anode 13 is provided between the pinning layer 12 and the contact layer 25A. Specifically, the anode 13 is a p-type semiconductor region (p++) having a higher concentration than the pinning layer 12, and is provided to electrically connect the pinning layer 12 and the contact layer 25A. A predetermined bias voltage is applied from the contact layer 25A to the pinning layer 12 through the anode 13.

In the photoelectric conversion section 2, for example, a strong negative voltage is applied to the anode 13 to cause a reverse voltage to be applied to the pn junction. As a result, a depletion layer widens from the pn junction between the p-type semiconductor region 14 and the n-type semiconductor region 15, and the high electric field multiplication region MR is formed. The photoelectric conversion section 2 can detect light incident on the light incident surface 10A with high sensitivity by avalanche multiplication of electrons generated by incident light in the multiplication region MR.

Here, an inter-pixel light-shielding section 33 is provided in contact with the pixel separation film TI on the light incident surface 10A side of the semiconductor substrate 10. The inter-pixel light-shielding section 33 is provided to surround the pixel P over the light incident surface 10A of the semiconductor substrate 10, and defines a light incident region RS of the pixel P. The inter-pixel light-shielding section 33 can prevent crosstalk between the pixels P by preventing leakage of light obliquely incident on the light incident surface 10A into the adjacent pixel P. The inter-pixel light-shielding section 33 includes a metal having a light shielding property, such as tungsten (W) or aluminum (Al), for example.

The light incident region RS is provided with an irregular section 36 in which irregularities are arranged in an array-shape on the light incident region RS at the light incident surface 10A side of the semiconductor substrate 10. Specifically, the irregular section 36 has a configuration in which square pyramid-shaped recesses are arranged in an array-shape, and is provided within the light incident region RS surrounded by the inter-pixel light-shielding section 33. Since the irregular section 36 can diffuse the incident light to the photoelectric conversion section 2 by diffraction or irregular reflection with the irregularities, the length of an optical path of the incident light in the photoelectric conversion section 2 can be further increased. Accordingly, the Irregular section 36 can further enhance the photon detection efficiency (PDE) of the photoelectric conversion section 2. Note that, such irregularities in the array-shape are formed, for example, by etching of the light incident surface 10A of the semiconductor substrate 10 along crystal planes.

In addition, an antireflection film 35 is provided on the light incident surface 10A of the semiconductor substrate 10 along the irregularities of the irregular section 36. The antireflection film 35 incudes, for example, a plurality of insulating thin films that has a high dielectric constant (High-k) and are laminated so that a refractive index gradually decreases from the semiconductor substrate 10 side. The antireflection film 35 can prevent reflection of the incident light by minimizing changes in reflectance with respect to the incident light. The antireflection film 35 may be, for example, a laminate that includes thin films containing silicon oxide (SiOₓ), hafnium oxide (HfO₂), aluminum oxide (Al₂O₃), titanium oxide (TiO₂), or strontium titanate (SrTiO₃). For example, the antireflection film 35 may have a configuration in which a first antireflection film 35A containing HfO₂, a second antireflection film 35B containing Al₂O₃, and a third antireflection film 35C containing SiOₓ are sequentially laminated from the semiconductor substrate 10 side.

Furthermore, an on-chip lens 34 is provided for each of the pixels P on the antireflection film 35 on the light incident surface 10A of the semiconductor substrate 10. The on-chip lens 34 has, for example, a convex shape obtained by inverting a bowl shape, and condenses the incident light on the multiplication region MR; thereby, the photon detection efficiency (PDE) of the photoelectric conversion section 2 can be further enhanced. The on-chip lens 34 may be obtained from, for example, an organic material or an inorganic material having optical transparency, such as thermoplastic resin or silicon nitride.

In the photodetector according to the present embodiment, an edge section 34A of the on-chip lens 34 falls within to be in contact with either the light incident region RS or the inter-pixel light-shielding section 33. Specifically, in FIG. 3, edge sections 34A of the on-chip lens 34 in an opposite side direction of the pixel P fall onto the inter-pixel light-shielding section 33, and edge sections 34A of the on-chip lens 34 in a diagonal direction of the pixel P fall within the light incident region RS. That is, the cross-section illustrated in FIG. 1 corresponds to a cross-section taken along line A-AA in FIG. 3, and the cross-section illustrated in FIG. 2 corresponds to a cross-section taken along line B-BB or line C-CC in FIG. 3.

In the photodetector, in order to enhance the photodetection sensitivity, it has been studied to further enlarge the height and opening of the on-chip lens 34 that condenses the incident light to the multiplication region MR. However, in a case where the height and opening of the on-chip lens 34 are enlarged until the edge sections 34A overlap the inter-pixel light-shielding section 33, light obliquely incident on the adjacent pixel P is reflected by a convex surface of the on-chip lens 34, so that light incident on the adjacent pixel P may be reduced.

In particular, in the pixels P provided in the peripheral section of the pixel array PA where the amount of obliquely incident light increases, a ratio of the amount of light reflected by the on-chip lens 34 to the amount of the light incident on the adjacent pixels P increases. Therefore, the photodetection sensitivity of the pixels P decreases because of a decrease in the amount of the incident light. In such a case, in the photodetector, the amount of incident light on the pixel P varies depending on a position in the pixel array PA, so that the photodetection sensitivity in the pixel array PA varies.

In the photodetector according to the present embodiment, the on-chip lens 34 is provided so that at least edge sections 34A fall within the light incident region RS which is an inner side of the inter-pixel light-shielding section 33 in the diagonal direction of the pixel P. According to this, since the on-chip lens 34 has a narrow opening and is separated from an adjacent pixel P at least in the diagonal direction of the pixel P, reflection of light obliquely incident on the adjacent pixel P can be prevented. Therefore, since the photodetector can reduce variation in lighting in the pixel array PA, variation in photodetection sensitivity in the pixel array PA can be reduced.

In such a case, as illustrated in FIG. 3, the on-chip lens 34 provided with the pixel P is provided in a shape in which a rectangular shape is deformed so as not to overlap with the inter-pixel light-shielding section 33 in the diagonal direction of the pixel P when viewed from a plan view. Specifically, the on-chip lens 34 may be provided in a shape in which the corners of the rectangular shape of the inter-pixel light-shielding section 33 are rounded in the diagonal direction of the pixel P when viewed from a plan view.

### 1.2. First Modification

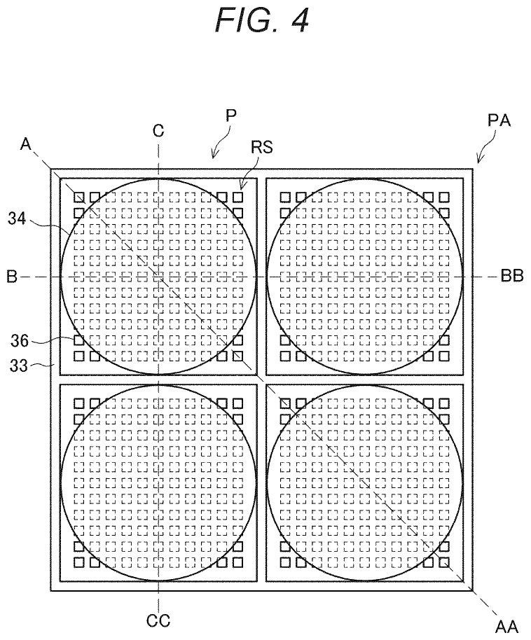

It is described in the above that the edge sections 34A of the on-chip lens 34 in the opposite side direction of the pixel P fall onto the inter-pixel light-shielding section 33, and the edge sections 34A of the on-chip lens 34 in the diagonal direction of the pixel P fall within the light incident region RS, but examples according to the present embodiment are not limited. For example, as illustrated in FIG. 4, all the edge sections 34A of the on-chip lens 34 in the opposite side direction and diagonal direction of the pixel P may fall within the light incident region RS. FIG. 4 is a plan view illustrating a correspondence relationship between the cross-sectional configuration illustrated in FIG. 1 and cutting lines on a plane of the pixel array PA in a first modification.

In FIG. 4, the edge sections 34A of the on-chip lens 34 in the diagonal direction of the pixel P fall within the light incident region RS, and the edge sections 34A of the on-chip lens 34 in the opposite side direction of the pixel P also fall within the light incident region RS in the same way. That is, the cross-section illustrated in FIG. 1 corresponds to a cross-section taken along line A-AA, line B-BB, or line C-CC in FIG. 4.

In the first modification, the on-chip lens 34 is provided so that the edge sections 34A fall within the light incident region RS which is an inner side of the inter-pixel light-shielding section 33 in the diagonal direction and opposite side direction of the pixel P. According to this, since the entire periphery of the on-chip lens 34 is separated from an adjacent pixel P, reflection of light that is obliquely incident on the adjacent pixel P can be further prevented. Therefore, since the photodetector can more effectively reduce variation in lighting in the pixel array PA, variation in photodetection sensitivity in the pixel array PA can be further reduced.

In such a case, as illustrated in FIG. 4, the on-chip lens 34 provided with the pixel P is provided in a shape in which the entire periphery of the pixel P does not overlap with the inter-pixel light-shielding section 33 when viewed from a plan view. Specifically, the on-chip lens 34 may be provided as a circle or rectangle that is one size smaller than the rectangular shape of the inter-pixel light-shielding section 33 when viewed from a plan view.

### 1.3. Second Modification

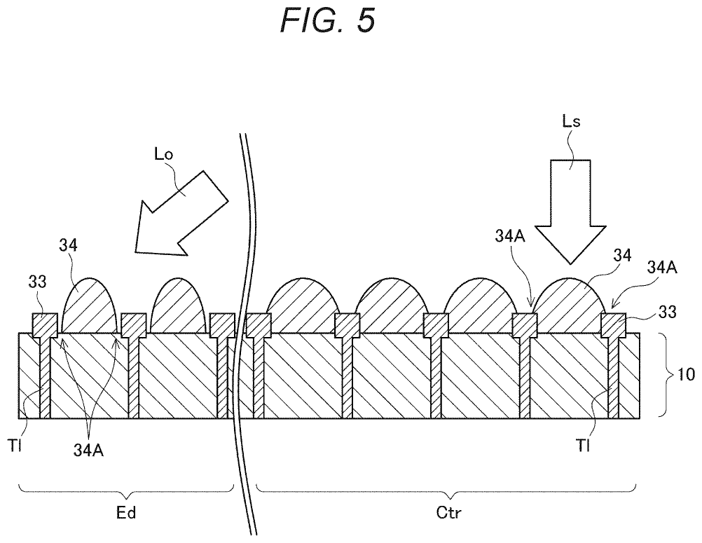

In the photodetector according to the present embodiment, it is sufficient that at least one or more pixels P with the cross-sectional configuration illustrated in FIG. 1 are present in the pixel array PA. On the other hand, in a second modification described with reference to FIG. 5, the photodetector controls an arrangement of the pixels P with the cross-sectional configuration illustrated in FIG. 1 in the pixel array PA, thereby reducing the variation in photodetection sensitivity in the pixel array PA while enhancing photodetection sensitivity in each of the pixels P. FIG. 5 is a schematic diagram illustrating shapes of the on-chip lenses 34 in each of a center section Ctr and a peripheral section Ed of the pixel array PA.

As illustrated in FIG. 5, the edge sections 34A of the on-chip lens 34 in the opposite side direction and diagonal direction of the pixel P may fall onto the inter-pixel light-shielding section 33 in the center section Ctr of the pixel array PA. On the other hand, in the peripheral section Ed of the pixel array PA, at least the edge sections 34A of the on-chip lens 34 in the diagonal direction of the pixel P may fall within the light incident region RS.

In the center section Ctr of the pixel array PA, since an incident light Ls is incident from a vertical direction with respect to each of the pixels P, reflection of the incident light to adjacent pixels P by a convex surface of the on-chip lens 34 is relatively decreased. Therefore, in the center section Ctr of the pixel array PA, the on-chip lens 34 may be provided with an opening widened until the edge sections 34A fall onto the inter-pixel light-shielding section 33 in order to condense more incident light.

On the other hand, in the peripheral section Ed of the pixel array PA, since an incident light Lo is incident from an oblique direction with respect to each of the pixels P, reflection of the incident light to the adjacent pixels P by a convex surface of the on-chip lens 34 is relatively increased. Therefore, in the peripheral section Ed of the pixel array PA, the on-chip lens 34 may be provided with a narrower opening so that the edge sections 34A fall within the light incident region RS in order to further prevent reflection of incident light to the adjacent pixels P.

Note that, the center section Ctr of the pixel array PA may be, for example, in a range where the pixel array PA is reduced by ½ based on the center of the pixel array PA. Furthermore, the peripheral section Ed of the pixel array PA may be, for example, in a range where the center section Ctr is excluded from the entire region of the pixel array PA. For example, in a case where the shape of the pixel array PA is a square, the center section Ctr may be a square region having the same center as the pixel array PA and having side lengths of ½ of the sides of the pixel array PA. Similarly, the peripheral section Ed may be a frame area having a width of ¼ of the lengths of the sides of the pixel array PA, excluding the center section Ctr from the entire pixel array PA.

In the second modification, according to a position (that is, the main incident angle of the incident light) of the pixel P in the pixel array PA, a position where the edge sections 34A of the on-chip lens 34 fall is controlled to either the inter-pixel light-shielding section 33 or the light incident region RS. That is, in the second modification, the on-chip lens 34 at a position where the amount of obliquely incident light is large is provided so that the edge sections 34A fall within the light incident region RS and the opening is narrowed to reduce the reflection of the incident light to the adjacent pixels P by the convex surface. On the other hand, the on-chip lens 34 at a position where the amount of vertically incident light is large is provided so that the edge sections 34A fall within the inter-pixel light-shielding section 33 and the opening is widened in order to condense more incident light.

Therefore, in the second modification, the photodetector can reduce the variation in the photodetection sensitivity of the pixel P between the center section Ctr and the peripheral section Ed in the pixel array PA while enhancing the photodetection sensitivity of the pixel P in the center section Ctr of the pixel array PA.

### 2. Second Embodiment

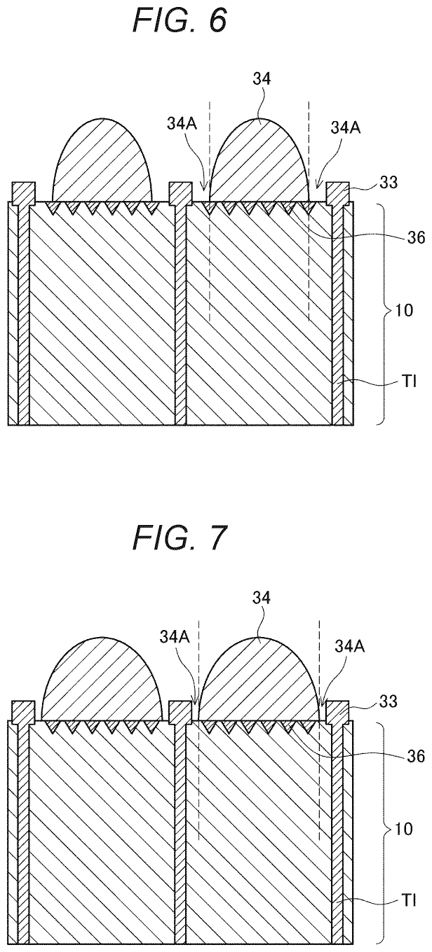

Subsequently, a pixel array PA included in a photodetector according to a second embodiment of the present disclosure will be described with reference to FIGS. 6 and 7. FIG. 6 is a schematic longitudinal cross-sectional view illustrating a first aspect of a positional relationship between an on-chip lens 34 and an irregular section 36 in the second embodiment. FIG. 7 is a schematic longitudinal cross-sectional view illustrating a second aspect of a positional relationship between the on-chip lens 34 and the irregular section 36 in the second embodiment. In the second embodiment, in addition to each of the configurations described in the first embodiment, the positional relationship between a falling position of edge sections 34A of the on-chip lens 34 and the irregular section 36 is further defined.

Specifically, as the first aspect, the edge sections 34A of the on-chip lens 34 may fall onto the irregular section 36 as illustrated in FIG. 6. That is, in the first aspect illustrated in FIG. 6, at least in the cross-section in the diagonal direction of the pixel P, the planar region covered by the on-chip lens 34 may be included in the irregular section 36. In such a case, light that has not been scattered by the irregular section 36 is less likely to enter the photoelectric conversion section 2, so that light with less noise and less variation is incident. According to this, the photodetector can prevent jitter that is fluctuation of timing in a time axis direction of photodetection from being increased.

On the other hand, as the second aspect, the edge sections 34A of the on-chip lens 34 may fall onto the light incident region RS outside the irregular section 36 as illustrated in FIG. 7. The light incident region RS outside the irregular section 36 is a flat section with a frame shape provided between the irregular section 36 and the inter-pixel light-shielding section 33. That is, in the second aspect illustrated in FIG. 7, at least in the cross-section in the diagonal direction of the pixel P, the irregular section 36 may be included in the planar region covered by the on-chip lens 34. In such a case, more incident light is condensed on the photoelectric conversion section 2 by the on-chip lens 34. According to this, the photodetector can further enhance the photon detection efficiency (PDE).

According to the second embodiment, the photodetector can further reduce the jitter or improve the photon detection efficiency according to the definition of the positional relationship between the falling position of the edge sections 34A of the on-chip lens 34 and the irregular section 36.

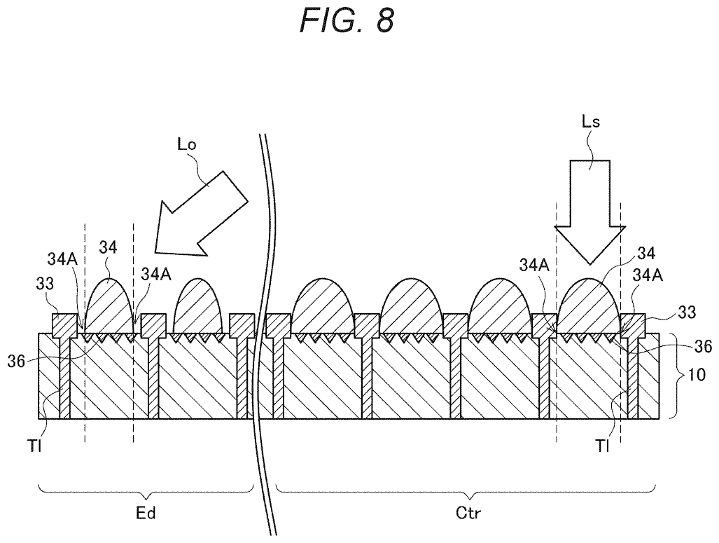

Here, a modification of the second embodiment will be described with reference to FIG. 8. In the modification of the second embodiment, the arrangement of the pixels P in the pixel array PA illustrated in FIGS. 6 and 7 can be controlled to reduce the jitter of the light detection while enhancing the photon detection efficiency. FIG. 8 is a schematic diagram illustrating shapes of the on-chip lenses 34 in each of a center section Ctr and a peripheral section Ed of the pixel array PA.

As illustrated in FIG. 8, in the center section Ctr of the pixel array PA, since the incident light Ls is incident from a vertical direction with respect to each of the pixels P, light with less variation is incident on the photoelectric conversion section 2. Therefore, in the center section Ctr of the pixel array PA, the on-chip lens 34 may be provided with an opening widened so that the edge sections 34A fall onto the light incident region RS outside the irregular section 36 in order to condense more incident light. Even in such a case, since uniform light with relatively less noise is incident on the photoelectric conversion section 2 of the pixel P provided in the center section Ctr of the pixel array PA, the photodetector can further enhance the photon detection efficiency (PDE) without increasing the jitter.

On the other hand, in the peripheral section Ed of the pixel array PA, since the incident light Lo is incident from an oblique direction with respect to each of the pixels P, light having a large variation in incident angle is incident on the photoelectric conversion section 2. Therefore, in the peripheral section Ed of the pixel array PA, the on-chip lens 34 may be provided with a narrower opening so that the edge sections 34A fall within the inner side of the irregular section 36 in order to further condense highly accurate incident light. Even in such a case, since uniform light with relatively less noise is incident on the photoelectric conversion section 2 of the pixel P provided in the peripheral section Ed of the pixel array PA, the photodetector can further prevent the jitter from being increased.

Note that, the center section Ctr of the pixel array PA may be, for example, in a range where the pixel array PA is reduced by 1/2 based on the center of the pixel array PA. Furthermore, the peripheral section Ed of the pixel array PA may be, for example, in a range where the center section Ctr is excluded from the entire region of the pixel array PA. For example, in a case where the shape of the pixel array PA is a square, the center section Ctr may be a square region having the same center as the pixel array PA and having side lengths of ½ of the sides of the pixel array PA. Similarly, the peripheral section Ed may be a frame area having a width of ¼ of the lengths of the sides of the pixel array PA, excluding the center section Ctr from the entire pixel array PA.

In the modification according to the second embodiment, according to a position (that is, the main incident angle of the incident light) of the pixel P in the pixel array PA, a position where the edge sections 34A of the on-chip lens 34 fall is controlled to either the light incident region RS or the irregular section 36. That is, in the modification of the second embodiment, the on-chip lens 34 at a position where the variation of the incident light is large is provided so that the edge sections 34A fall within the irregular section 36 and the opening is narrowed in order to allow the light with higher accuracy to be incident on the photoelectric conversion section 2. In contrast, the on-chip lens 34 at a position where the variation of the incident light is small is provided so that the edge sections 34A fall within the light incident region RS outside the irregular section 36 and the opening is widened in order to allow more incident light to be condensed on the photoelectric conversion section 2.

Therefore, according to the modification of the second embodiment, the photodetector can reduce the jitter in the photodetection for the pixels P in the center section Ctr and the peripheral section Ed in the pixel array PA while enhancing the photon detection efficiency of the pixel P in the center section Ctr of the pixel array PA.

### 3. Application Example

### Photodetection Device

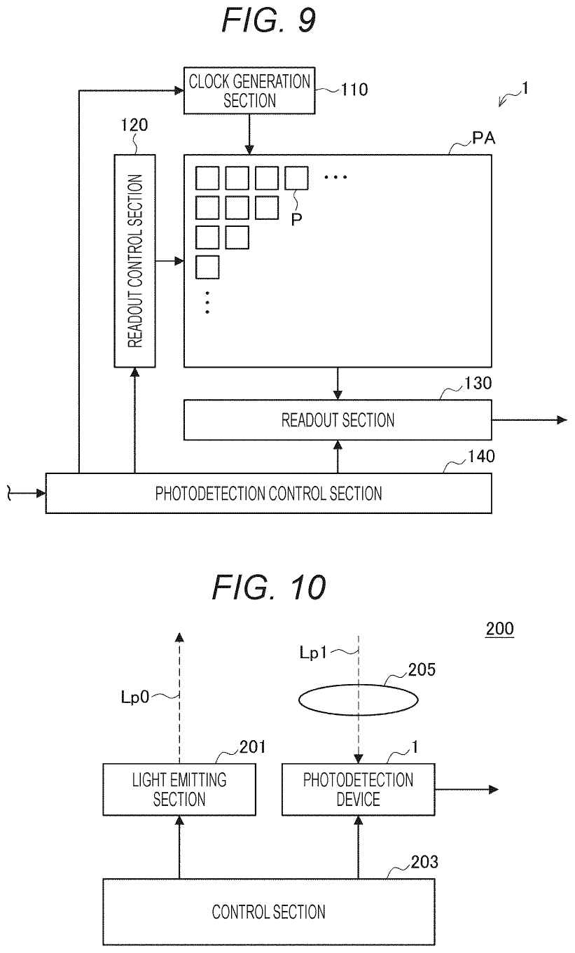

FIG. 9 is a schematic diagram illustrating a configuration of a photodetection device 1 that includes the photodetector according to the first or second embodiment. As illustrated in FIG. 9, the photodetection device 1 is provided with a pixel array PA, a clock generation section 110, a readout control section 120, a readout section 130, and a photodetection control section 140.

The pixel array PA includes the above-described plurality of pixels P each of which detects light, the pixels P being arranged in a matrix. On the basis of inputs from the clock generation section 110 and the readout control section 120, signal charges corresponding to incident light are output from each photoelectric conversion section 2 included in the pixel P to the readout section 130. The pixel array PA corresponds to the photodetector in the present disclosure.

The photodetection control section 140 controls an operation of each section of the photodetection device 1. Specifically, the photodetection control section 140 can control the operation of the photodetection device 1 by controlling the operations of the clock generation section 110, the readout control section 120, and the readout section 130.

The clock generation section 110 generates a clock signal indicating a master clock serving as a reference of operation timing of each section of the photodetection device 1. The generated clock signal is output to each of the pixels P included in the pixel array PA.

The readout control section 120 selectively scans each of the pixels P included in the pixel array PA to read out signal charges corresponding to incident light from each of the pixels P to be output to the readout section 130.

The readout section 130 performs various digital signal processing and other processing on the signal charges output from the pixel array PA, followed by outputting the signal charges to the outside of the photodetection device 1 as photodetection signals.

### Distance Measuring Device

FIG. 10 is a schematic diagram illustrating a configuration of a distance measuring device 200 that includes the photodetection device 1 illustrated in FIG. 9. As illustrated in FIG. 10, the distance measuring device 200 includes a light emitting section 201, an optical system 205, a photodetection device 1, and a control section 203.

The light emitting section 201 emits a light pulse Lp0 to a distance measurement target. The light emitting section 201 may emit the light pulse Lp0 by alternately repeating light emission and non-light emission on the basis of an instruction from the control section 203. The light emitting section 201 may include, for example, a laser light source or a light source of light emitting diodes (LEDs), which emit infrared rays.

The optical system 205 includes a lens and other components, and forms an image with light on a light receiving surface of the photodetection device 1. Specifically, the optical system 205 forms an image with a light pulse Lp1 (for example, infrared rays) emitted from the light emitting section 201 and reflected by the distance measurement target on the light receiving surface of the photodetection device 1.

The photodetection device 1 detects incident light on the basis of an instruction from the control section 203, thereby externally outputting information regarding a distance to the distance measurement target. For example, the photodetection device 1 may derive information regarding the distance to the distance measurement target on the basis of the delay time between a detection signal of the incident light and the reference signal.

The control section 203 outputs a control signal to the light emitting section 201 and the photodetection device 1 to control the operations of the light emitting section 201 and the photodetection device 1, thereby controlling the overall operation of the distance measuring device 200.

### Application Example to Mobile Body

The technology according to the present disclosure (present technology) can be applied to various products. For example, the technology of the present disclosure may be achieved in the form of a photodetection device to be mounted in a mobile object of any kind, such as an automobile, an electric vehicle, a hybrid electric vehicle, a motorcycle, a bicycle, a personal mobility, an airplane, a drone, a vessel, or a robot.

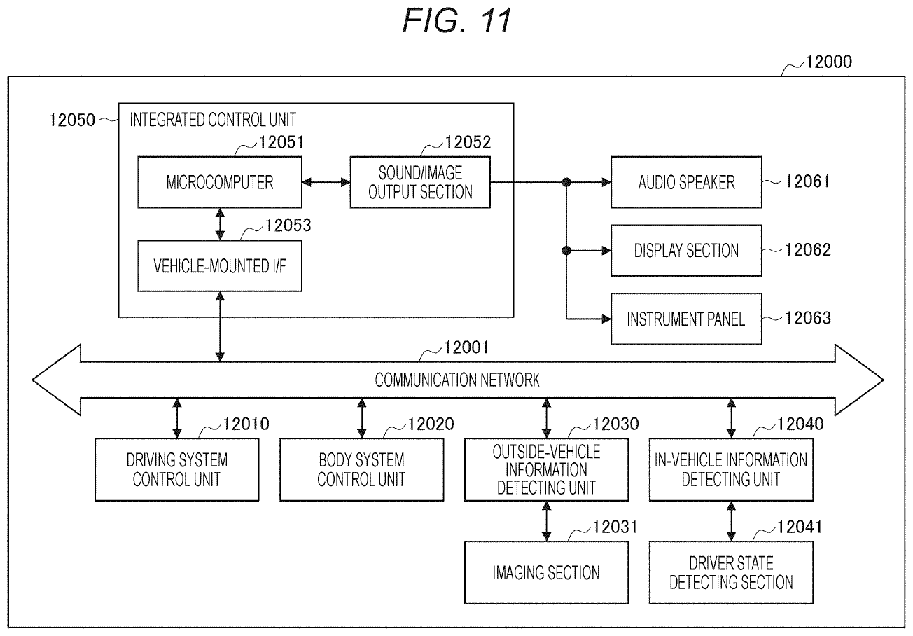

FIG. 11 is a block diagram illustrating an example of schematic configuration of a vehicle control system as an example of a mobile body control system to which the technology according to the present disclosure can be applied.

The vehicle control system 12000 includes a plurality of electronic control units connected to each other via a communication network 12001. In the example illustrated in FIG. 11, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of information on the outside of the vehicle, the information being obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 11, an audio speaker 12061, a display section 12062, and an instrument panel 12063 are illustrated as the output device. The display section 12062 may, for example, include at least one of an on-board display and a head-up display.

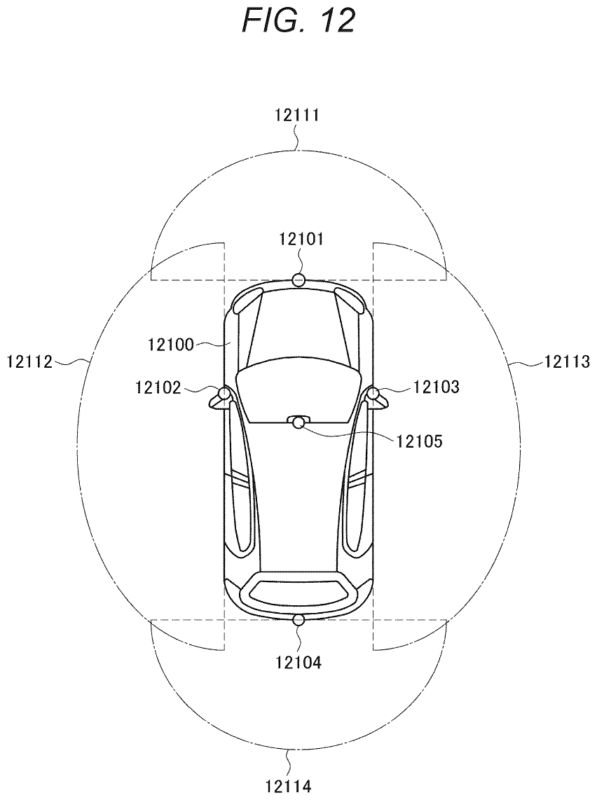

FIG. 12 is a diagram illustrating an example of the installation position of the imaging section 12031.

In FIG. 12, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that, FIG. 12 illustrates an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 or various non-illustrated distance measuring sensors among the above-described configurations. By applying the technology according to the present disclosure to the imaging section 12031 or the distance measuring sensors, the vehicle control system can measure and recognize the external environment of the vehicle with higher accuracy.

The preferred embodiments of the present disclosure have been described above in detail with reference to the accompanying drawings, but the technical scope of the present disclosure is not limited to such examples. It is obvious that those with ordinary skill in the technical field of the present disclosure can conceive various alterations or corrections within the scope of the technical idea recited in the claims, and it is naturally understood that these alterations or corrections also fall within the technical scope of the present disclosure.

Furthermore, the effects described in the present specification are merely exemplary or illustrative, and not restrictive. That is, the technology according to the present disclosure can exhibit other effects apparent to those skilled in the art from the description of the present specification, in addition to the effects described above or instead of the effects described above.

Note that the following configurations also fall within the technological scope of the present disclosure.
(1)

A photodetector including:
a semiconductor substrate in which a photoelectric conversion section is provided;
an inter-pixel light-shielding section that is provided over the semiconductor substrate and defines a light incident region of a pixel corresponding to the photoelectric conversion section; and
an on-chip lens that is provided on the light incident region of the semiconductor substrate,
in which at least edge sections of the on-chip lens in a diagonal direction of the pixel fall onto the light incident region.
(2)

The photodetector according to (1), in which the edge sections of the on-chip lens in an opposite side direction of the pixel fall onto the inter-pixel light-shielding section.
(3)

The photodetector according to (1), in which the edge sections of the on-chip lens in an opposite side direction of the pixel fall onto the light incident region.
(4)

The photodetector according to any one of (1) to (3), in which the pixel including the on-chip lens which has the edge sections falling onto the light incident region is provided at least in a peripheral section of a pixel array in which a plurality of the pixels is planarly arranged in a matrix.
(5)

The photodetector according to any one of (1) to (4), in which the light incident region is provided with an irregular section in which irregularities are arranged in an array-shape over a surface of the semiconductor substrate.
(6)

The photodetector according to (5), in which the irregularities include square pyramid-shaped recesses.
(7)

The photodetector according to (5) or (6), in which at least the edge sections of the on-chip lens in the diagonal direction fall onto the irregular section.
(8)

The photodetector according to (5) or (6), in which at least the edge sections of the on-chip lens in the diagonal direction fall onto the light incident region outside the irregular section.
(9)

The photodetector according to (5) or (6),
in which the pixel including the on-chip lens which has the edge sections falling onto the irregular section is provided in a peripheral section of a pixel array in which a plurality of the pixels is planarly arranged in a matrix, and
the pixel including the on-chip lens which has the edge sections falling onto the light incident region outside the irregular section is provided in a center section of the pixel array.
(10)

The photodetector according to any one of (1) to (9), in which in the photoelectric conversion section, an infrared ray is subjected to photoelectric conversion.
(11)

The photodetector according to any one of (1) to (10), in which the photoelectric conversion section includes a single photon avalanche diode.
(12)

A photodetection device including: a photodetector; and a processing circuitry that performs signal processing on an output from the photodetector,
in which the photodetector includes
a semiconductor substrate in which a photoelectric conversion section is provided,
an inter-pixel light-shielding section that is provided over the semiconductor substrate and defines a light incident region of a pixel corresponding to the photoelectric conversion section, and
an on-chip lens that is provided on the light incident region of the semiconductor substrate, and
at least edge sections of the on-chip lens in a diagonal direction of the pixel fall onto the light incident region.

### REFERENCE SIGNS LIST

2 Photoelectric conversion section
10 Semiconductor substrate
10A Light incident surface
10B Surface
11 Well layer
12 Pinning layer
13 Anode
14 p-type semiconductor region
15 n-type semiconductor region
16 Cathode
24 Insulating film
25A Contact layer
25B First wiring
25C First connection layer
25D Second wiring
25E Second connection layer
25F Third wiring
26 Wiring layer
30 Pixel separation groove
33 Inter-pixel light-shielding section
34 On-chip lens
34A Edge section
35 Antireflection film
35A First antireflection film
35B Second antireflection film
35C Third antireflection film
36 Irregular section
Ctr Center section
Ed Peripheral section
MR Multiplication region
P Pixel
PA Pixel array
RS Light incident region
TI Pixel separation film
V Void

What is claimed is:

1. A photodetector, comprising:
a semiconductor substrate in which a photoelectric conversion section is provided;
an inter-pixel light-shielding section that is provided over the semiconductor substrate and defines a light incident region of a pixel corresponding to the photoelectric conversion section; and
an on-chip lens that is provided on the light incident region of the semiconductor substrate,
wherein at least edge sections of the on-chip lens in a diagonal direction of the pixel fall onto the light incident region.

2. The photodetector according to claim 1, wherein the edge sections of the on-chip lens in an opposite side direction of the pixel fall onto the inter-pixel light-shielding section.

3. The photodetector according to claim 1, wherein the edge sections of the on-chip lens in an opposite side direction of the pixel fall onto the light incident region.

4. The photodetector according to claim 1, wherein the pixel including the on-chip lens which has the edge sections falling onto the light incident region is provided at least in a peripheral section of a pixel array in which a plurality of the pixels is planarly arranged in a matrix.

5. The photodetector according to claim 1, wherein the light incident region is provided with an irregular section in which irregularities are arranged in an array-shape over a surface of the semiconductor substrate.

6. The photodetector according to claim 5, wherein the irregularities include square pyramid-shaped recesses.

7. The photodetector according to claim 5, wherein at least the edge sections of the on-chip lens in the diagonal direction fall onto the irregular section.

8. The photodetector according to claim 5, wherein at least the edge sections of the on-chip lens in the diagonal direction fall onto the light incident region outside the irregular section.

9. The photodetector according to claim 5,
wherein the pixel including the on-chip lens which has the edge sections falling onto the irregular section is provided in a peripheral section of a pixel array in which a plurality of the pixels is planarly arranged in a matrix, and
the pixel including the on-chip lens which has the edge sections falling onto the light incident region outside the irregular section is provided in a center section of the pixel array.

10. The photodetector according to claim 1, wherein in the photoelectric conversion section, an infrared ray is subjected to photoelectric conversion.

11. The photodetector according to claim 1, wherein the photoelectric conversion section includes a single photon avalanche diode.

12. A photodetection device, comprising: a photodetector; and a processing circuitry that performs signal processing on an output from the photodetector,
wherein the photodetector includes
a semiconductor substrate in which a photoelectric conversion section is provided,
an inter-pixel light-shielding section that is provided over the semiconductor substrate and defines a light incident region of a pixel corresponding to the photoelectric conversion section, and
an on-chip lens that is provided on the light incident region of the semiconductor substrate, and
at least edge sections of the on-chip lens in a diagonal direction of the pixel fall onto the light incident region.
